(19) United States
(12) Patent Application Publication
(10) Pub. No.: US 2013/0002268 A1
(43) Pub. Date: Jan. 3, 2013

(54) DISTRIBUTED SENSORS TO MEASURE CEMENT STATE

(75) Inventors: Sunil Kumar, Celle (DE); Joerg Lehr, Celle (DE)

(73) Assignee: BAKER HUGHES INCORPORATED, Houston, TX (US)

(21) Appl. No.: 13/173,668

(22) Filed: Jun. 30, 2011

(51) Int. Cl. G01R 27/26

(52) U.S. Cl. 324/679

(57) ABSTRACT

A system for determining a curing state for cement disposed in a borehole penetrating the earth that includes a transceiver that includes a transmitting coil and that is configured to provide an input signal to the coil that sweeps through a frequency range and to measure the magnitude of the voltage across the coil. The system also includes a plurality of sensor nodes disposed in the concrete. The sensor nodes include a receiving coil and a capacitor coupled to the receiving coil to form a receiving circuit and that has a capacitance that changes as one of pressure or strain in the cement changes.

### BACKGROUND

1. Field of the Invention

The present invention generally relates to sensors and, in particular, to systems that utilize sensors to measure the state of cement.

2. Description of the Related Art

Boreholes are drilled deep into the earth for many applications such as carbon dioxide sequestration, geothermal production, and hydrocarbon exploration and production. In all of the applications, the boreholes are drilled such that they pass through or allow access to a material (e.g., a gas or fluid) contained in a formation located below the earth's surface. Many different types of tools and instruments may be disposed in the boreholes to perform various tasks and measurements.

Boreholes are typically completed such that they exhibit a composite pipe in pipe construction that can resist high pressures and temperatures. The construction consists of an inner and an outer pipe whose annular gap is filled with cement. When a section of the well is cased and cemented, resumption of drilling must be delayed until the cement cures. If the drilling is resumed prematurely, the cement, which has not had sufficient time to set, can be destroyed. Unnecessary delay however, is associated with excess cost that is preferably avoided. Therefore, it is important to determine the state of the cement as accurately as possible.

The curing time of cement is affected by the pressure, shear stresses and the temperature of the cement. The pressure and shear stresses depend on process parameters i.e. altitude of the cement and volume flow. The temperature is affected by the temperature of the cement just prior to application, the heat released by the exothermic reaction and the heat transfer of the formation to the cement. As long as the pressure, shear stresses and temperature are known, curing time can be determined.

In addition to knowing when the cement has cured, it is also desirable to know the properties of the cured cement right after curing and over its entire life. The properties can include, for instance, the presence of bubbles or gaps in the cement.

### BRIEF SUMMARY

Disclosed is a system for determining a curing state for cement disposed in a borehole penetrating the earth that includes a transceiver that includes a transmitting coil and that is configured to provide an input signal to the coil that sweeps through a frequency range and to measure the magnitude of the voltage across the coil. The system also includes a plurality of sensor nodes disposed in the concrete. The sensor nodes include a receiving coil and a capacitor coupled to the receiving coil to form a receiving circuit and that has a capacitance that changes as one of pressure or strain in the cement changes.

Also disclosed is a method of determining a curing state of cement disposed in a borehole penetrating the earth. The method includes disposing a plurality of sensor nodes that includes a receiving coil and a capacitor that form a receiving circuit in a cement slurry, the capacitor having a capacitance that changes based on one of a pressure or a strain; disposing the cement slurry into the borehole; lowering a transceiver into the borehole internal to the cement slurry, the transceiver including a transmitting coil; sweeping a frequency of a voltage applied to the transmitting coil over a frequency range as the transceiver is being lowered in the borehole; measuring a magnitude of the voltage; and determining the curing state based on dips in the measured magnitude.

Further disclosed is a system for determining a property of cement disposed in a borehole penetrating the earth that includes a transceiver that includes a transmitting coil and that is configured to provide an input signal to the coil that sweeps through a frequency range and to measure the magnitude of the voltage across the coil. The system also includes a plurality of sensor nodes disposed in the concrete. The sensors include a receiving coil and a capacitor coupled to the receiving coil to form a receiving circuit and that has a capacitance that changes as one of pressure or strain in the cement changes.

### BRIEF DESCRIPTION OF THE DRAWINGS

The following descriptions should not be considered limiting in any way. With reference to the accompanying drawings, like elements are numbered alike:

FIG. 1 is a cut-away side view of a borehole that includes casing and production casing cemented to the casing;

FIG. 2 is a cut-away side view of another borehole that includes casing and production casing cemented to the casing; and

FIG. 3 is a circuit diagram showing a transceiver and a sensor node that can be utilized to carry out embodiments of the invention.

### DETAILED DESCRIPTION

A detailed description of one or more embodiments of the disclosed apparatus and method presented herein is by way of exemplification and not limitation with reference to the Figures.

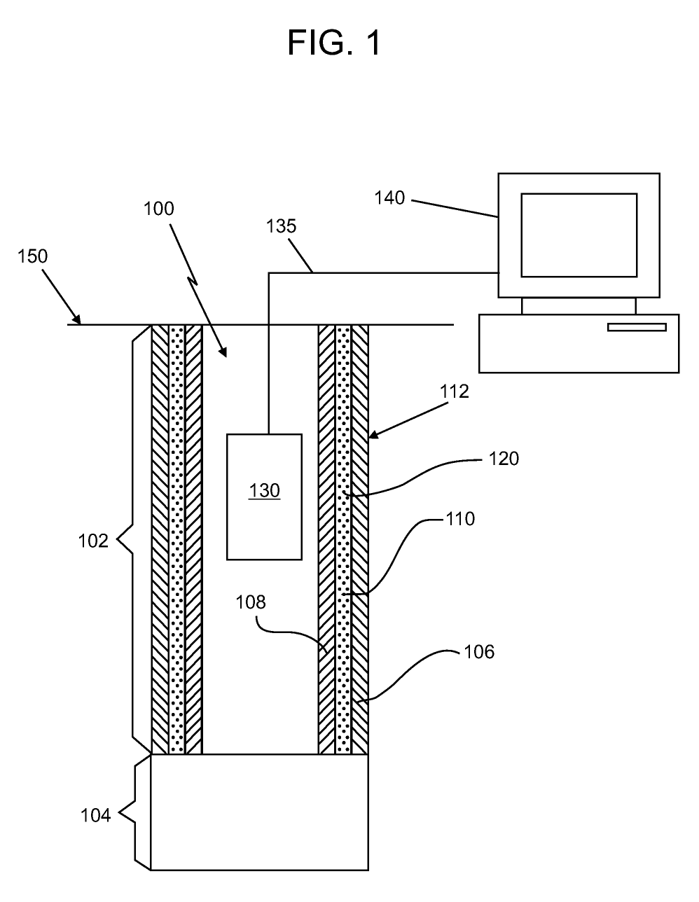

FIG. 1 shows a borehole 100 that includes a completed section 102 and a non-completed section 104. In the completed section 102 there exists at least two casing layers 106, 108. As illustrated, an outer casing 106 contacts a wall 112 of the borehole 100. Of course, other layers or elements could be disposed between the outer casing 106 and the wall 112. The exact configuration of the casing layers 106, 108 can vary from that illustrated in FIG. 1 as long as at some location along the depth of the borehole 100, the two casing layers 106, 108 overlap and are separated from one another by a layer of cement 110.

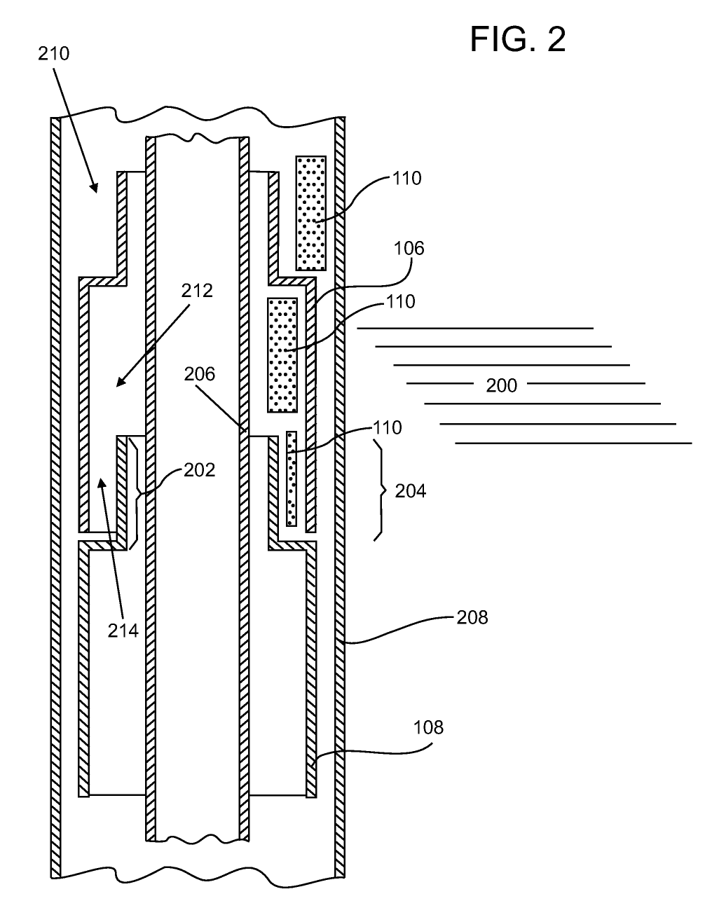

According to one embodiment, at least a portion of the inner casing 108 is disposed within the outer casing 106. For example, and with reference now to FIG. 2, the inner casing 108 includes a top portion 202 that fits within a bottom portion 204 of the outer casing 106. As illustrated in FIG. 2, both the inner and outer casing 108, 106, surround a production tube 206. A parent drilling liner 208 contacts a formation 200 through which the borehole 100 passes. In FIG. 2, several voids 210, 212, 214, respectively, exist between the outer casing 106 and the parent drilling liner 208, the inner and outer casings 108, 106 and the outer casing 106 and the production tube 206. It shall be understood that one or more of the voids 210, 212, 214 are filled with cement 110 at some point during the completion of the borehole.

In both of the cases illustrated in FIGS. 1 and 2, according to an embodiment of the present invention, the cement 110 includes one or more sensing nodes 120 disposed therein. Referring again to FIG. 1, the sensing nodes 120 can be activated and read by transceiver 130 that is lowered into the borehole 100. The transceiver 130, described in greater detail below, interacts with the sensing nodes 120 to determine temperature, strain or both of the cement 110 in an area directly surrounding the particular sensor node 120.

In one embodiment, the sensing nodes include a coil (inductor) coupled to a capacitor that varies in capacitance based on the surrounding temperature or strain. As the transceiver 130 is lowered into or raised out of the borehole 100, the temperature/strain values measured by the sensor nodes 120 is transmitted to a computing device 140 via a wireline 135. At the computing device 140, a determination as to whether the cement 110 has cured sufficiently such that drilling can resume can be made based on the one or both the temperature and strain values. It shall be understood that, in one embodiment, the location of the computing device 140 can be moved to another surface 150 location (i.e., it can be remote from the transceiver 130). In another embodiment, the computing device 140 can be part of the transceiver 130.

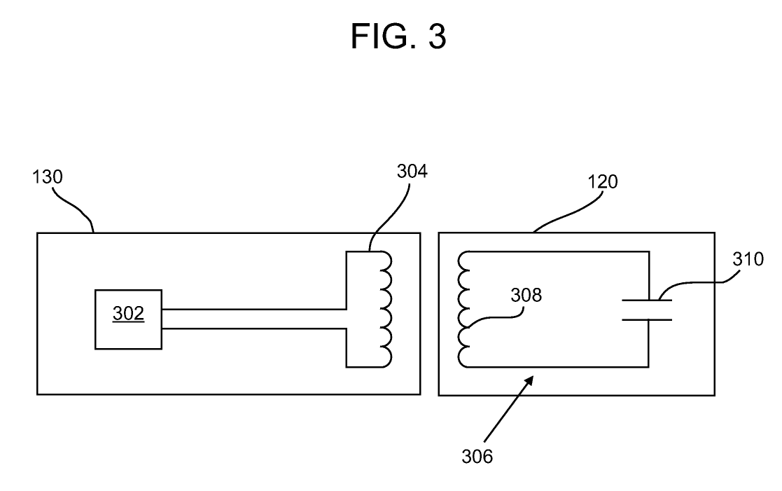

FIG. 3 shows transceiver 130 arranged to communicate with a sensor node 120. It shall be understood, that the sensor node 120 can be encapsulated in a material that allows it to be mixed into a cement slurry. The cement slurry is flowed into the annulus of a borehole 100 where it becomes the cement 110 illustrated in FIGS. 1 and 2 when cured. The sensor node 120 assists in making the determination that the cement 110 has cured.

The sensor node 120 includes a coil 308 coupled to a capacitor 310 that form a receiving circuit 306. The coil 308 an the capacitor 310 form an LC circuit that has a resonant frequency ω that generally is generally defined as shown in equation 1:

$$ω = \frac{1}{\sqrt{LC}} \qquad ( 1 )$$

where L is the inductance of the coil 308 and C is the capacitance of the capacitor 310.

According to one embodiment, the transceiver 130 includes a control circuit 302 that drives a transmitting coil 304. According to one embodiment, the control circuit 302 varies the frequency at which the transmitting coil 304 transmits. In particular, the control circuit 302 can provide an input signal to the transmitting coil 304 that has a frequency that sweeps through a frequency range.

The control circuit 302 can measure the voltage v across the coil 308. As the input to the transmitting coil 308 is swept through the resonant frequency of the receiving circuit 306, the magnitude of the voltage v across the transmitting coil 308 will drop due to the increased coupling between the transmitting coil 304 and receiving circuit 306. The voltage can be continuously measured or measured at times when the transmitting coil 308 is being driven at specific frequencies.

According to one embodiment, the capacitor 310 is formed such that its capacitance varies with strain or pressure. For instance, and as will be understood of one of skill in the art, the capacitor 310 can include a flexible plate the compression or shearing of which causes the distance between it an the other plate to vary. The variation in distance between the capacitor plates will, of course, cause the capacitance (C) of the capacitor 310 to change. As the capacitor 310 changes is capacitance, the resonant frequency ω of the receiving circuit 306 changes. Thus, by monitoring voltage levels at the transmitting coil 304, the capacitance of capacitor 310 can be determined. In more detail, the frequency at which the voltage, v. drops is the resonant frequency ω of the receiving circuit 306. From equation 1, the capacitance of the capacitor 310 can be determined at the resonant frequency assuming L is known. Given the capacitance of the capacitor 310, the pressure or strain can be determined based on known responses of the capacitor 310 to either temperature or pressure. In one embodiment, in contrast to some prior art devices, the sensor nodes 120 do not include a power supply such as a battery or storage capacitor coupled to the receiving circuit 106.

It shall be understood that in one embodiment, the capacitance may be fixed such that some or all of the sensors nodes 120 has a fixed resonant frequency. This fixed resonant frequency can be used to identify each node 120 individually. In such a case, the general location of each of the sensors nodes can be determined. Based on the position, the speed of movement of the cement can be determined. From speed, viscosity can be determined.

It shall be understood that while the term “cement” is used through out the above description, that term can be interpreted to include any filling material between downhole tubing and a formation or other tubing or that serves to strengthen or seal a borehole. It shall further be understood that while pressure and strain are measured, the location of the detected sensor nodes 120 can also be used to determine the volumetric distribution of the cement in the borehole.

Elements of the embodiments have been introduced with either the articles “a” or “an.” The articles are intended to mean that there are one or more of the elements. The terms “including” and “having” are intended to be inclusive such that there may be additional elements other than the elements listed. The conjunction “or” when used with a list of at least two terms is intended to mean any term or combination of terms. The terms “first,” “second,” and “third” are used to distinguish elements and are not used to denote a particular order.

It will be recognized that the various components or technologies may provide certain necessary or beneficial functionality or features. Accordingly, these functions and features as may be needed in support of the appended claims and variations thereof, are recognized as being inherently included as a part of the teachings herein and a part of the invention disclosed.

While the invention has been described with reference to exemplary embodiments, it will be understood that various changes may be made and equivalents may be substituted for elements thereof without departing from the scope of the invention. In addition, many modifications will be appreciated to adapt a particular instrument, situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A system for determining a curing state for cement disposed in a borehole penetrating the earth, the system comprising:
a transceiver that includes a transmitting coil and that is configured to provide an input signal to the coil that sweeps through a frequency range and to measure the magnitude of the voltage across the coil; and
a plurality of sensor nodes disposed in the concrete that includes:
a receiving coil; and
a capacitor coupled to the receiving coil to form a receiving circuit and that has a capacitance that changes as one of pressure or strain in the cement changes.

2. The system of claim 1, wherein the plurality of sensor nodes do not include a power source coupled to the receiving coil or capacitor.

3. The system of claim 1, further comprising:
a computing device that receives the magnitude of the voltage, determines the resonant frequency of the receiving circuit from the magnitude of the voltage and, from the resonant frequency determines the curing state.

4. A method of determining a curing state of cement disposed in a borehole penetrating the earth comprising:
disposing a plurality of sensor nodes that includes a receiving coil and a capacitor that form a receiving circuit in a cement slurry, the capacitor having a capacitance that changes based on one of a pressure or a strain;
disposing the cement slurry into the borehole;
lowering a transceiver into the borehole internal to the cement slurry, the transceiver including a transmitting coil;
sweeping a frequency of a voltage applied to the transmitting coil over a frequency range as the transceiver is being lowered in the borehole;
measuring a magnitude of the voltage; and
determining the curing state based on dips in the measured magnitude.

5. The method of claim 4, wherein the dips occur at a frequency that match a resonant frequency of the receiving circuit.

6. A system for determining a property of cement disposed in a borehole penetrating the earth, the system comprising:
a transceiver that includes a transmitting coil and that is configured to provide an input signal to the coil that sweeps through a frequency range and to measure the magnitude of the voltage across the coil; and
a plurality of sensor nodes disposed in the concrete that includes:
a receiving coil; and
a capacitor coupled to the receiving coil to form a receiving circuit and that has a capacitance that changes as one of pressure or strain in the cement changes.

7. The system of claim 6, further comprising:
a computing device that receives the magnitude of the voltage, determines the resonant frequency of the receiving circuit from the magnitude of the voltage and, from the resonant frequency determines the property.

8. The system of claim 7, wherein the property is one of: curing state of the cement and the volumetric distribution of the cement.
